(19) United States
(12) Patent Application Publication
(10) Pub. No.: US 2016/0102394 A1
(43) Pub. Date: Apr. 14, 2016

(54) METHOD FOR PREPARING GROUNDING SUBSTRATE FOR SEMICONDUCTOR DEVICE

(71) Applicant: Shenyang Fortune Precision Equipment Co., Ltd., Shenyang (CN)

(72) Inventors: Tianying XIONG, Shenyang (CN); Jie WU, Shenyang (CN); Jiqiang WANG, Shenyang (CN); Yanfang SHEN, Shenyang (CN); Xinyu CUI, Shenyang (CN); Tianliang MAO, Shenyang (CN); Ming LI, Shenyang (CN); Minjie WU, Shenyang (CN); Maocheng LI, Shenyang (CN); Weidong TANG, Shenyang (CN); Xuecheng HAN, Shenyang (CN); Xinhai GU, Shenyang (CN); Weijie LIU, Shenyang (CN)

(21) Appl. No.: 14/789,966

(22) Filed: Jul. 1, 2015

(30) Foreign Application Priority Data
Oct. 9, 2014 (CN) 201410528539.4

(51) Int. Cl. C23C 4/12; C23C 4/08; H01L 21/48

(52) U.S. Cl. CPC C23C 4/128; H01L 21/4835; H01L 21/4842; C23C 4/08

(57) ABSTRACT

A method for preparing a grounding substrate for a semiconductor device, the method including: 1) polishing the surface of a matrix of a grounding substrate to remove a carbon layer therefrom, and washing the surface of the matrix with anhydrous ethanol; 2) providing a cold spray system including a spraying device, a spray chamber, and a special fixture disposed in the spray chamber; and disposing the matrix on the special fixture; 3) using the cold spray system to spray a compressed gas carrying aluminum powder on the surface of the matrix at the supersonic speed to form an aluminum coating, thus obtaining the grounding substrate; 4) disposing the grounding substrate in a heat treatment furnace, raising the temperature therein to between 100 and 500° C., and maintaining the temperature for between 1 and 5 hrs; and 5) wet polishing the grounding substrate.

### CROSS-REFERENCE TO RELATED APPLICATIONS

Pursuant to 35 U.S.C. §119 and the Paris Convention Treaty, this application claims the benefit of Chinese Patent Application No. 201410528539.4 filed Oct. 9, 2014, the contents of which are incorporated herein by reference. Inquiries from the public to applicants or assignees concerning this document or the related applications should be directed to: Matthias Scholl P.C., Attn.: Dr. Matthias Scholl Esq., 245 First Street, 18th Floor, Cambridge, Mass. 02142.

### BACKGROUND OF THE INVENTION

1. Field of the Invention

The invention relates to a method for preparing a grounding substrate for a semiconductor device.

2. Description of the Related Art

When a grounding piece of a semiconductor device works in the coexistence of high temperature plasma radiation and fluoride gas, high conductivity and high temperature creep resistance are required.

Pure aluminum is an ideal conducting material for a semiconductor device because it features excellent conductivity and minimum pollution of the components in the process of etching, lithography, and coating. However, pure aluminum has relatively low fusion point, so that it is inadaptable to the continuously increasing temperature of the chamber.

Although stainless steel and nickel-base alloys exhibit superb high temperature performance, they have poor conductivity, and toxic iron and nickel ions are discharged under strong plasma irradiation, which pollutes the processing environment and destroys the components in the etching, lithography, and coating processes.

Prior to this disclosure, a useful method for preparing a grounding substrate for a semiconductor by cold or hot spraying of a pure aluminum on the surface of a stainless steel or nickel-base alloy has not been reported.

### SUMMARY OF THE INVENTION

In view of the above-described problems, it is one objective of the invention to provide a method for preparing a grounding substrate for a semiconductor device. Materials having good mechanical properties at high temperature, such as stainless steel, nickel-base alloy, or heat-resistant steel, are utilized as the matrix for the high temperature creep resistant grounding substrate for the semiconductor device, so as to obtain a non-oxidized pure aluminum coating layer having uniform thickness and excellent bonding property on the surface of the matrix. In one respect, the conductivity and the compatibility of the large-scale circuit technology of the pure aluminum are utilized, and in the other respect, the mechanical properties of the matrix are utilized to solve the insufficiency in the high temperature creep resistance of the grounding substrate.

To achieve the above objective, in accordance with one embodiment of the invention, there is provided a method for preparing a grounding substrate for a semiconductor device, and the method comprises:
1) polishing a surface of a matrix of a grounding substrate using a 320# sandpaper for texture treatment whereby removing a carbon layer therefrom, and washing the surface of the matrix with anhydrous ethanol;
2) providing a cold spray system comprising a spraying device, a spray chamber, and a special fixture disposed in the spray chamber; and disposing the matrix on the special fixture;
3) using the cold spray system to spray a compressed gas carrying aluminum powder on the surface of the matrix at a supersonic speed to form an aluminum coating, whereby obtaining the grounding substrate, wherein, parameters for the spraying process are as follows: a spray distance is between 5 and 50 mm, a gas pressure is between 0.5 and 4.5 megapascal, a gas temperature is between 150 and 500° C., a gas flow rate is between 5 and 50 g/s, a purity of the aluminum powder is above 90%, and a grain size of the aluminum powder is between 200 and 600 meshes;
4) disposing the grounding substrate in a heat treatment furnace, raising a temperature therein to between 100 and 500° C., and maintaining the temperature for between 1 and 5 hrs; and
5) wet polishing the grounding substrate using a scouring pad and ethanol for eliminating color differences on the surface of the matrix.

In a class of this embodiment, the special fixture comprises: a base, a side wall, and an upper plate; the side wall comprises a pumping port communicating with a vacuum pump; and the upper plate comprises a plurality of suction holes. When in use, the matrix is disposed on the suction holes and adhered to the special fixture when the vacuum pump is started.

In a class of this embodiment, the matrix is made of a stainless steel, a nickel-base alloy, or a heat-resistant steel.

In a class of this embodiment, a thickness of the matrix is between 0.1 and 0.6 mm.

In a class of this embodiment, the spray device comprises: a gas inlet pipe, a heater, a powder feeder, and a supersonic nozzle. One end of the gas inlet pipe communicates with a high pressure gas source, and the other end of the gas inlet pipe communicates with the supersonic nozzle respectively via the powder feeder and the heater. The surface of the matrix is disposed opposite the supersonic nozzle.

In a class of this embodiment, the supersonic nozzle comprises: a gas inlet, a convergent section, a throat, a divergent section, and an outlet. The supersonic nozzle is disposed at an inlet of the spray chamber. When in use, the compressed gas is divided into two paths. One path of the compressed gas is introduced to the powder feeder and functions as a carrier gas to carry the aluminum powder to the supersonic nozzle, and the other path of the compressed gas is introduced to the heater for gas expansion whereby increasing the gas flow rate and heating the aluminum powder. The two paths of the compressed gas are introduced to the supersonic nozzle whereby forming a gas-liquid double-phase flow. Aluminum grains in the gas-liquid double-phase flow are knocked onto the surface of the matrix, plastically deformed, and deposited on the surface of the matrix to form an aluminum conducting layer.

In a class of this embodiment, the compressed gas is air, nitrogen gas, or helium gas.

Advantages according to embodiments of the invention are summarized as follows:
1. The method of the invention is the application of the cold spray method on the high temperature creep resistant grounding substrate for semiconductor device, the prepared coating layer has uniform thickness, excellent bonding with the substrate, and low porosity, thereby improving the conductivity of the grounding substrate.
2. The method employs a cold gas dynamic spray process, and the pure aluminum powder forms the coating layer mainly based on the plastic deformation and the deposition. The spray temperature is much lower than the fusion point of the aluminum, so that the coating layer has low oxygen content, and the conductivity of the grounding substrate is improved.
3. The method of the invention features high deposition efficiency, small energy consumption, no thermal irradiation, recycling of the aluminum powder, simple operation, security, low production cost, and no environment pollution.
4. The grounding substrate of the semiconductor device is also called the soft substrate because it is very thin and in a flexible state. It is difficult to realize uniform thickness and good bonding force when spraying the conducting coating layer on the soft substrate. The soft substrate is adhered to the special fixture by vacuum pumping, and the aluminum coating layer formed by such a method has uniform thickness and excellent bonding force.

In summary, the process of the invention can realize deposition of the aluminum coating layer at low temperature, such a process has almost no thermal impact on the metal powder structure, and the metal coating deposition is realized merely by supersonic speed of the grains. Thus, the method is adapted to form a coating layer on the nickel-base alloy on the premise of not affecting the performance of the substrate material, thereby being an important processing method for preparing high performance non-oxidized coating layer. In addition, the conducting coating layer of excellent performance has been successfully prepared on the nickel-base alloy by adopting the cold spray method of the invention.

### BRIEF DESCRIPTION OF THE DRAWINGS

The invention is described hereinbelow with reference to the accompanying drawings, in which:

FIG. 1 is a structure diagram of a cold spray system in accordance with one embodiment of the invention;

FIG. 2 is a picture showing morphology of a sectional view of a coating layer under SEM in accordance with one embodiment of the invention;

FIG. 3 is a picture showing morphology of a coating layer under SEM in accordance with one embodiment of the invention;

FIG. 4 is a structure diagram of a supersonic nozzle in accordance with one embodiment of the invention; and

FIG. 5 is a structure diagram of a special fixture in accordance with one embodiment of the invention.

### DETAILED DESCRIPTION OF THE EMBODIMENTS

For further illustrating the invention, experiments detailing a method for preparing a grounding substrate for a semiconductor device are described below. It should be noted that the following examples are intended to describe and not to limit the invention.

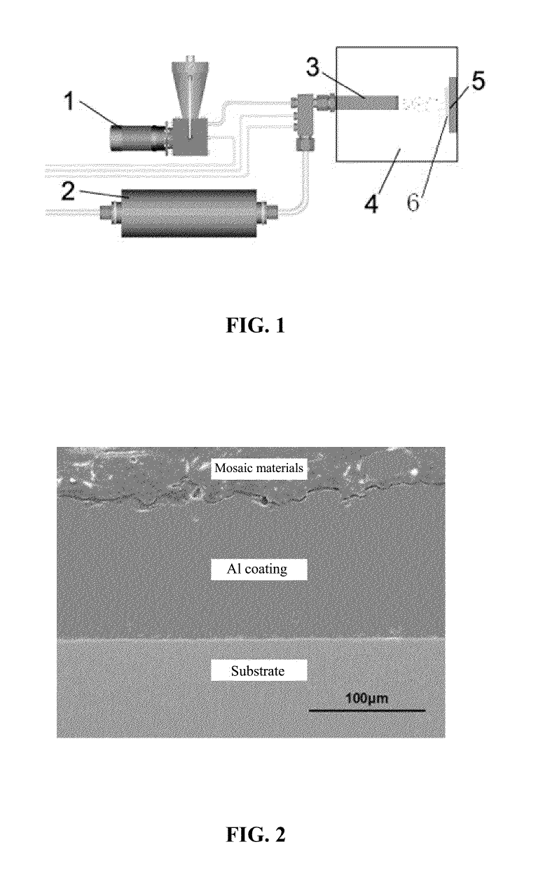

As shown in FIGS. 1-5, a method for preparing a high temperature creep resistant grounding substrate for a semiconductor device is specifically performed as follows:
1) Pretreatment of a matrix 6 of a grounding substrate: a nickel-base alloy having a size of 620×64×0.2 mm is used as a matrix 6. A surface of the matrix 6 is conducted with texture treatment, and the process parameter for the texture treatment is 320# sandpaper polishing for removing a carbon layer from the surface of the matrix. Thereafter, the matrix 6 is washed by anhydrous ethanol.
2) A cold spray system is provided. The cold spray system comprises: a spraying device, a spray chamber 4, and a special fixture 5 disposed in the spray chamber 4. The matrix 6 is disposed on the special fixture 5 of the cold spray system. The spray device comprises: a gas inlet pipe, a heater 2, a powder feeder 1, and a supersonic nozzle 3. One end of the gas inlet pipe communicates with a high pressure gas source, and the other end of the gas inlet pipe communicates with the supersonic nozzle 3 respectively via the powder feeder 1 and the heater 2. The supersonic nozzle 3 is disposed at an inlet of the spray chamber 4. The surface of the matrix is disposed opposite the supersonic nozzle 3. The supersonic nozzle 3 comprises a convergent section 31, a throat 32, and a divergent section 33. The convergent section 31 is a subsonic section in a smooth and continuous convergent structure in a Witoszynski curve and is transitionally connected to the throat. The divergent section 33 is a supersonic section in an axisymmetric flow structure and is transitionally connected to the throat. The divergent section 33 comprises: an original expansion section 331 and a wave absorption section 332. The original expansion section 331 is a smooth and continuous transition structure, and a spring flow region is disposed therein. The wave absorption section 332 is an axial symmetric structure in parallel to an axis, and a uniform region is disposed therein. The convergent section 31 is respectively connected to the powder feeder 1 and the heater 2 via transition pipe fittings. The special fixture comprises: a base 7, a side wall 8, and an upper plate 9. The side wall 8 comprises a pumping port 11 communicating with a vacuum pump. The upper plate 9 comprises a plurality of suction holes 10. When in use, the matrix 6 is disposed on the suction holes 10 and adhered to the special fixture 5 when the vacuum pump is started.
3) Spraying: the spray device is adopted. A compressed nitrogen gas carrying with the aluminum powder is sprayed to the surface of the matrix at an ultrasonic speed. The compressed nitrogen gas is divided into two paths, one path of the compressed gas is introduced to the powder feeder 1 and functions as a carrier gas to carry the aluminum powder to the supersonic nozzle 3, and the other path of the compressed gas is introduced to the heater 2 for gas expansion so as to increase the gas flow rate and heat the aluminum powder. The two paths of the compressed nitrogen gas are then introduced to the supersonic nozzle 3 where a gas-liquid double-phase flow is formed. Aluminum grains having high kinetic energy in the gas-liquid double-phase flow are knocked onto the surface of the matrix, plastically deformed, and deposited on the surface of the matrix to form an aluminum conducting layer, thereby yielding the grounding substrate. Parameters for spraying process are as follows: a spray distance is 35 mm, a gas pressure is between 3 megapascal, a gas temperature is between 300° C., a gas flow rate is between 30 g/s, a purity of the aluminum powder is 99%, and a grain size of the aluminum powder is between 300 meshes.
4) Heat treatment after spraying: the grounding substrate is disposed in a heat treatment furnace, a temperature therein is raised to between 100 and 500° C., and the temperature is maintained for between 1 and 5 hrs.
5) Subsequent treatment of the coating surface: the grounding substrate is wet polished using a scouring pad and ethanol so as to eliminate color differences on the surface of the matrix.

Morphology of a sectional view of a coating layer of the grounding substrate under the SEM is shown in FIG. 2. The thickness of the coating layer is uniform and approximately 120 μm. The coating layer is compact and in the absence of obvious holes, and the coating layer and the substrate are well bonded.

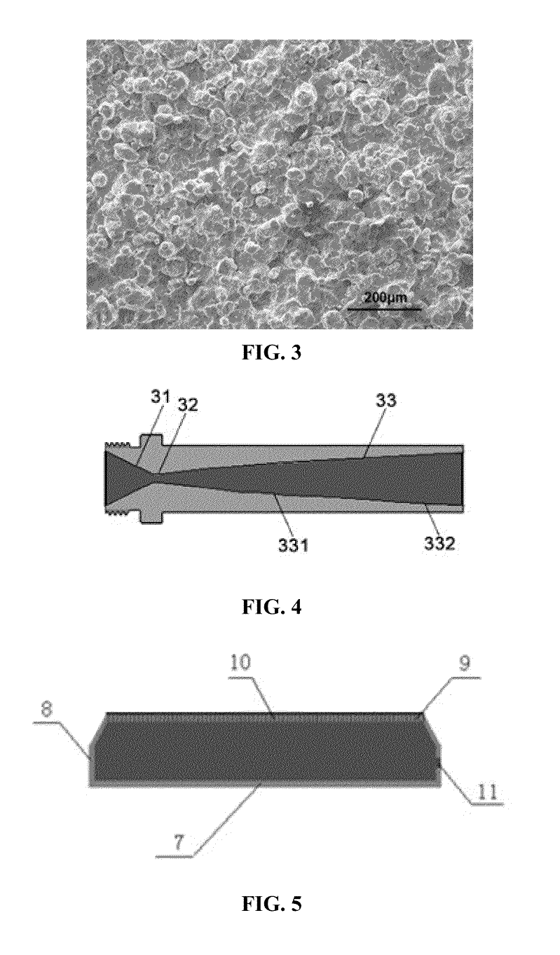

Morphology of a coating layer of the grounding substrate under the SEM is shown in FIG. 3. The coating surface is uniform and compact, a large amount of aluminum grains are distributed on the coating surface, and the quality of the whole coating layer is relatively good.

While particular embodiments of the invention have been shown and described, it will be obvious to those skilled in the art that changes and modifications may be made without departing from the invention in its broader aspects, and therefore, the aim in the appended claims is to cover all such changes and modifications as fall within the true spirit and scope of the invention.

The invention claimed is:

1. A method for preparing a grounding substrate for a semiconductor device, the method comprising:
1) polishing a surface of a matrix of a grounding substrate using a 320# sandpaper for texture treatment whereby removing a carbon layer therefrom, and washing the surface of the matrix with anhydrous ethanol;
2) providing a cold spray system comprising a spraying device, a spray chamber, and a special fixture disposed in the spray chamber; and disposing the matrix on the special fixture;
3) using the cold spray system to spray a compressed gas carrying aluminum powder on the surface of the matrix at a supersonic speed to form an aluminum coating, whereby obtaining the grounding substrate, wherein, parameters for a spraying process are as follows: a spray distance is between 5 and 50 mm, a gas pressure is between 0.5 and 4.5 megapascal, a gas temperature is between 150 and 500° C., a gas flow rate is between 5 and 50 g/s, a purity of the aluminum powder is above 90%, and a grain size of the aluminum powder is between 200 and 600 meshes;
4) disposing the grounding substrate in a heat treatment furnace, raising a temperature therein to between 100 and 500° C., and maintaining the temperature for between 1 and 5 hrs; and
5) wet polishing the grounding substrate using a scouring pad and ethanol for eliminating color differences on the surface of the matrix.

2. The method of claim 1, wherein
the special fixture comprises: a base, a side wall, and an upper plate; the side wall comprises a pumping port communicating with a vacuum pump; and the upper plate comprises a plurality of suction holes;
when in use, the matrix is disposed on the suction holes and adhered to the special fixture when the vacuum pump is started.

3. The method of claim 1, wherein the matrix is made of a stainless steel, a nickel-base alloy, or a heat-resistant steel.

4. The method of claim 3, wherein a thickness of the matrix is between 0.1 and 0.6 MM.

5. The method of claim 1, wherein the spray device comprises: a gas inlet pipe, a heater, a powder feeder, and a supersonic nozzle; one end of the gas inlet pipe communicates with a high pressure gas source, and the other end of the gas inlet pipe communicates with the supersonic nozzle via the powder feeder and the heater; and the surface of the matrix is disposed opposite to the supersonic nozzle.

6. The method of claim 5, wherein
the supersonic nozzle comprises: a gas inlet, a convergent section, a throat, a divergent section, and an outlet;
the supersonic nozzle is disposed at an inlet of the spray chamber;
when in use:
the compressed gas is divided into two paths, one path of the compressed gas is introduced to the powder feeder and functions as a carrier gas to carry the aluminum powder to the supersonic nozzle, and the other path of the compressed gas is introduced to the heater for gas expansion whereby increasing the gas flow rate and heating the aluminum powder; the two paths of the compressed gas are introduced to the supersonic nozzle whereby forming a gas-liquid double-phase flow; and
aluminum grains in the gas-liquid double-phase flow are knocked onto the surface of the matrix, plastically deformed, and deposited on the surface of the matrix to form an aluminum conducting layer.

7. The method of claim 6, wherein the compressed gas is air, nitrogen gas, or helium gas.
